(19) United States
(12) Patent Application Publication
(10) Pub. No.: US 2002/0020880 A1
(43) Pub. Date: Feb. 21, 2002

(54) ESD PROTECTION CIRCUIT IMMUNE TO LATCH-UP DURING CIRCUIT OPERATION

(76) Inventor: TA-LEE YU, HSINCHU HSIEN (TW)

Correspondence Address: RICHARD P BERG, LADAS & PARRY, 5670 WILSHIRE BOULEVARD, SUITE #2100, LOS ANGELES, CA, 900365679

(21) Appl. No.: 09/412,829

(22) Filed: Oct. 5, 1999

(30) Foreign Application Priority Data
Jul. 31, 1999 (TW) 88113087

(51) Int. Cl. H01L 23/62; H01L 23/552

(52) U.S. Cl. 257/360

(57) ABSTRACT

An ESD protection circuit of the present invention comprises a semiconductor controlled rectifier and at least one diode connected in series. The series-connected semiconductor controlled rectifier and diode are electrically coupled between a pair of circuit nodes. Even though the semiconductor controlled rectifier enters snapback during circuit operation the diode can be utilized to increase a holding voltage between the pair of circuit nodes. The required number of diodes is based upon the design consideration so that proper trigger voltage and holding voltage can be acquired. The semiconductor controlled rectifier can be a lateral semiconductor controlled rectifier, a low voltage triggering semiconductor controlled rectifier, or a floating-well semiconductor controlled rectifier.

### BACKGROUND OF THE INVENTION

1. Field of the Invention

The present invention generally relates to integrated circuit protection techniques. More particularly, the present invention relates to an ESD protection circuit immune to latch-up during circuit operation.

2. Description of the Related Art

Sub-micron CMOS ICs have become increasingly vulnerable to ESD damage due to advanced processes, such as the use of lightly-doped drain structures and clad silicide diffusions. Conventionally, lateral semiconductor-controlled rectifiers (LSCRs), for example, disclosed in U.S. Pat. No. 5,012,317, have been employed as ESD protection circuits for shunting ESD stress. A cross-sectional view of the conventional LSCR is illustrated in FIG. 1.

Referring to FIG. 1, the LSCR is fabricated onto a P-type semiconductor substrate 10, for example a silicon substrate, in a predetermined portion of which an N-well region 11 is formed. A P⁺-type diffusion region 12 and an N⁺-type diffusion region 13 are formed within the extent of the N-well region 11 and spaced apart from each other. An N⁺-type diffusion region 14 and a P⁺-type diffusion region 15 are formed within the extent of the P-type semiconductor substrate 10 and spaced apart from each other, where the N⁺-type diffusion region 14 is closer to the N-well region 11 than the P⁺-type diffusion region 15.

In FIG. 1, the P⁺-type diffusion region 12 and the N⁺-type diffusion region 13 are together connected to an IC pad 1. The IC pad 1 is an input pad, output pad, I/O pad or power pad for an internal circuit 2, which is vulnerable to ESD damage and should be protected by the LSCR. In addition, the N⁺-type diffusion region 14 and the P⁺-type diffusion region 15 are together connected to a V_{SS} power node. Generally, the V_{SS} power node is electrically coupled to a ground potential V_{SS} under circuit operation, that is, the internal circuit 2 is powered by V_{DD} of 5 V or 3.3 V and V_{SS}.

Correspondingly, the P⁺-type diffusion region 12, the N-well region 11, and the P-type semiconductor substrate 10 serve as the emitter, base, and collector, respectively, of a PNP bipolar junction transistor 20. The N-well region 11, the P-type semiconductor substrate 10, and the N⁺-type diffusion region 14 serve as the collector, base, and emitter, respectively, of an NPN bipolar junction transistor 21. Referring to FIG. 2, the schematic circuit diagram of the conventional LSCR of FIG. 1 is illustrated. In FIG. 2, resistors 22 and 23 designate the respective spreading resistance of the N-well region 11 and the P-type semiconductor substrate 10.

However, during circuit operation the conventional LSCR may be susceptible to latch-up by virtue of external noise or electromagnetic interference, and thus the internal circuit 2 may fail to perform properly.

### SUMMARY OF THE INVENTION

Therefore, it is an object of the present invention to provide an ESD protection circuit immune to latch-up during circuit operation.

For attaining the above-identified object, the present invention provides an ESD protection circuit comprising a semiconductor controlled rectifier and at least one diode connected in series. The series-connected scheme is electrically coupled between a pair of circuit nodes. Even though the semiconductor controlled rectifier enters snapback during circuit operation the diode can be utilized to increase a holding voltage between the pair of circuit nodes.

The required number of diode is based upon the design consideration so that proper trigger voltage and holding voltage can be acquired. If the holding voltage is adjusted to be greater than or substantially equal to V_{IH}, the ESD protection circuit of the present invention can be applied at an IC input pad to ensure that an internal circuit work properly during the circuit operation. Preferably, if the holding voltage can be adjusted to be greater than or substantially equal to V_{DD}, the ESD protection circuit of the present invention can be thoroughly immune to latch-up phenomenon during the circuit operation, even in an environment of noise and electromagnetic interference.

Moreover, the semiconductor controlled rectifier can be a lateral semiconductor controlled rectifier, a low voltage triggering semiconductor controlled rectifier, or even a floating-well semiconductor controlled rectifier.

### BRIEF DESCRIPTION OF DRAWINGS

The following detailed description, given by way of examples and not intended to limit the invention to the embodiments described herein, will best be understood in conjunction with the accompanying drawings, in which:

FIG. 1 schematically illustrates a cross-sectional view of the conventional LSCR fabricated onto a semiconductor substrate;

FIG. 2 is a schematic circuit diagram of FIG. 1;

FIG. 3 is a schematic circuit diagram of a first preferred embodiment in accordance with the present invention;

FIG. 4 is a graph showing I-V curves indicative of the performance of the circuits shown in FIGS. 2 and 3 for comparison;

FIG. 5 is a schematic circuit diagram of a second preferred embodiment in accordance with the present invention;

FIG. 6 is a schematic circuit diagram of a third preferred embodiment in accordance with the present invention; and

FIG. 7 is a schematic circuit diagram of a fourth preferred embodiment in accordance with the present invention.

### DETAILED DESCRIPTION OF THE INVENTION

FIRST EMBODIMENT

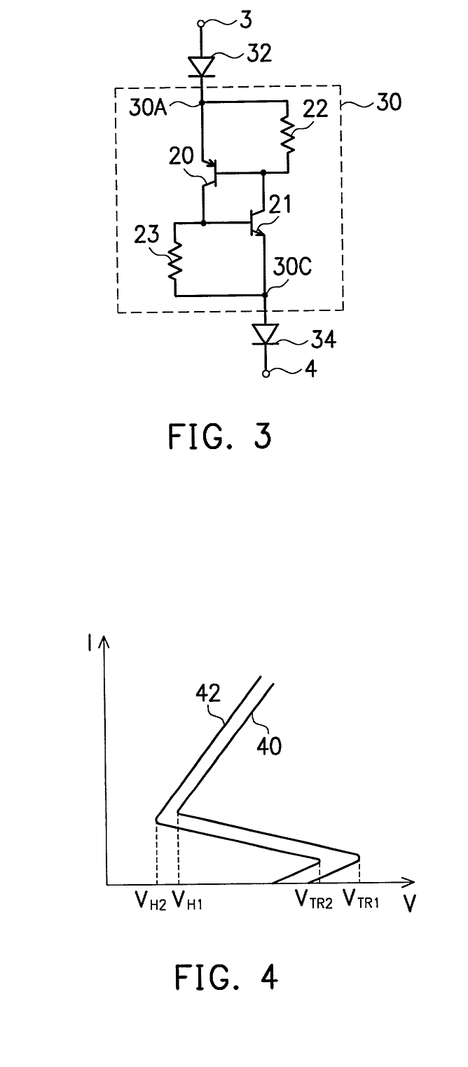

Referring to FIG. 3, a schematic circuit diagram of a first preferred embodiment in accordance with the present invention is illustrated. In this embodiment, an ESD protection circuit is electrically coupled between a pair of circuit nodes 3 and 4, which can be an IC pad and a V_{SS} power node, respectively. According to the present invention, the ESD protection circuit comprises a LSCR 30 and at least one diode, where two diodes 32 and 34 are exemplified in FIG. 3.

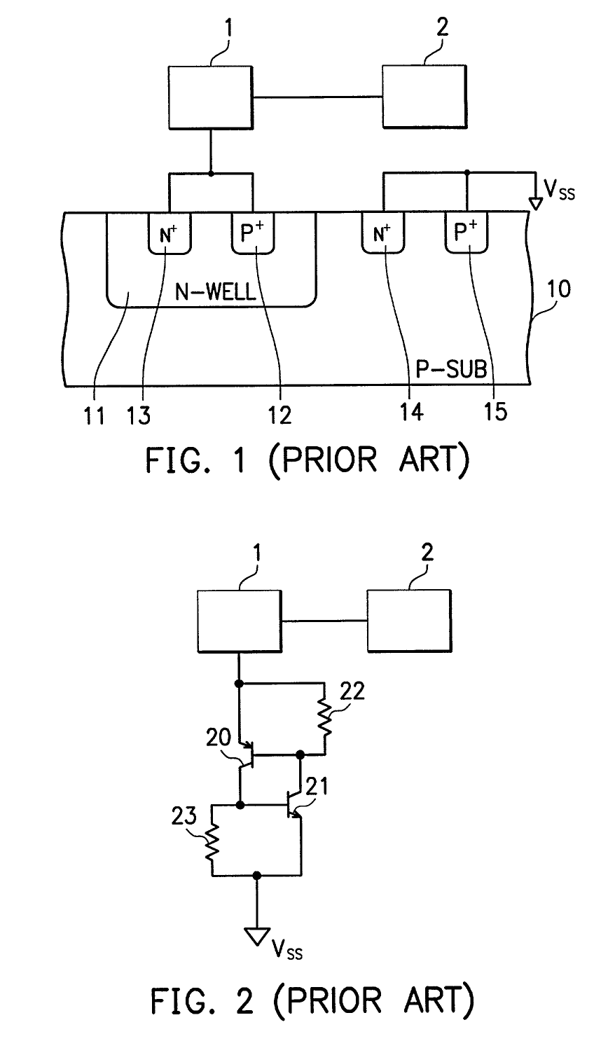

The LSCR 30, which can be realized by means of the structure as shown in FIG. 1, is provided with an anode terminal 30A and a cathode terminal 30C. The diode 32 is configured with its anode and cathode connected to the circuit node 3 and the anode terminal 30A of the LSCR 30, respectively. The diode 34 is configured with its anode and cathode connected to the cathode terminal 30C of the LSCR 30 and the circuit node 4, respectively.

Referring to FIG. 4, a graph showing I-V curves indicative of the performance of the circuits shown in FIGS. 2 and 3 is illustrated for comparison, wherein the I-V curve 40 designates the circuit performance of FIG. 3 and the I-V curve 42 designates the circuit performance of the conventional LSCR as shown in FIG. 1. As depicted in FIG. 4, the curve 40 is right shifted along a voltage-axis from the curve 42, thus approximately in parallel with the curve 42. Therefore, the ESD protection circuit of FIG. 3 has a trigger voltage V_{TR1} greater than a trigger voltage V_{TR2} of the conventional LSCR of FIG. 1. Similarly, the ESD protection circuit of FIG. 3 has a holding voltage V_{H1} higher than a holding voltage V_{H2} of the conventional LSCR of FIG. 1 as well. Assuming that both of the diodes 32 and 34 are provided with the same cut-in voltage V_{γ} and N represents the number of the diodes, the trigger voltages V_{TR1}, V_{TR2} and the holding voltages V_{H1}, V_{H2} has the following relationship:

V_{TR1}≈(V_{TR2}+N×V_{γ})

V_{H1}≈(V_{H2}+N×V_{γ})

Although two diodes 32 and 34 are exemplified in this embodiment, the required number can be one or more than two based upon the design choice so that the proper trigger voltage and holding voltage can be acquired. Generally speaking, the holding voltage V_{TR1} is adjusted to be greater than or substantially equal to V_{IH}, denoting the minimum input voltage to be regarded as logic high with respect to an inverter, the ESD protection circuit of FIG. 3 can be applied at an IC input pad to ensure that the internal circuit 2 work properly during the circuit operation. Preferably, if the holding voltage V_{H1} can be adjusted to be greater than or substantially equal to V_{DD}, the ESD protection circuit of FIG. 3 can be thoroughly immune to latch-up phenomenon during the circuit operation, even in an environment of noise and electromagnetic interference.

SECOND EMBODIMENT

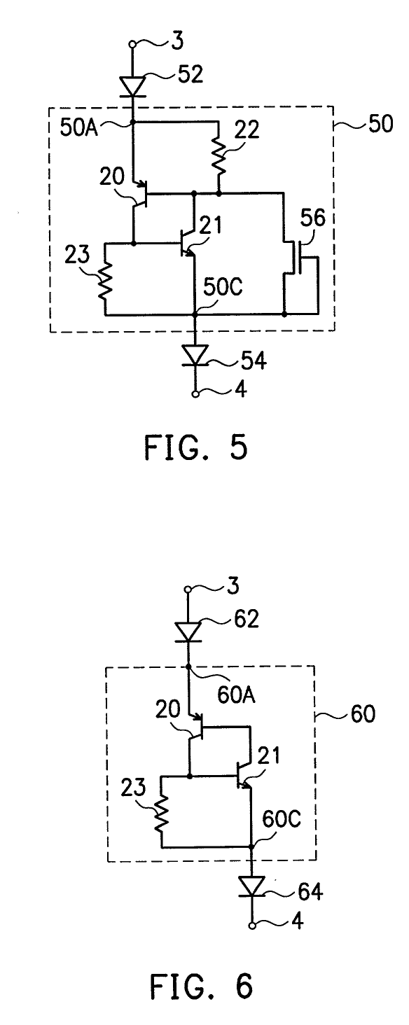

Referring to FIG. 5, a schematic circuit diagram of a second preferred embodiment in accordance with the present invention is illustrated. In this embodiment, an ESD protection circuit is electrically coupled between a pair of circuit nodes 3 and 4, which can be an IC pad and a V_{SS} power node, respectively. The ESD protection circuit comprises a low voltage triggering semiconductor controlled rectifier 50, hereinafter LVTSCR, and at least one diode, where two diodes 52 and 54 are exemplified in FIG. 5.

The LVTSCR 50 has been disclosed in U.S. Pat. No. 5,465,189 with a MOS-like structure 56 spanning a junction between the N-well 11 and the semiconductor substrate 10 as depicted in FIG. 1. The LVTSCR 50 is provided with an anode terminal 50A and a cathode terminal 50C. The diode 52 is configured with its anode and cathode connected to the circuit node 3 and the anode terminal 50A of the LVTSCR 50, respectively. The diode 54 is configured with its anode and cathode connected to the cathode terminal 50C of the LVTSCR 50 and the circuit node 4, respectively.

THIRD EMBODIMENT

Referring to FIG. 6, a schematic circuit diagram of a third preferred embodiment in accordance with the present invention is illustrated. In this embodiment, an ESD protection circuit is electrically coupled between a pair of circuit nodes 3 and 4, which can be an IC pad and a V_{SS} power node, respectively. The ESD protection circuit comprises a floating-well semiconductor controlled rectifier 60 and at least one diode, where two diodes 62 and 64 are exemplified in FIG. 6.

The floating-well SCR 60 is implemented by means of the structure as shown in FIG. 1, except for the N⁺-type diffusion region 13, so that the N-well region 11 is floating. The floating-well SCR 60 is provided with an anode terminal 60A and a cathode terminal 60C. The diode 62 is configured with its anode and cathode connected to the circuit node 3 and the anode terminal 60A of the floating-well SCR 60, respectively. The diode 64 is configured with its anode and cathode connected to the cathode terminal 60C of the floating-well SCR 60 and the circuit node 4, respectively.

FOURTH EMBODIMENT

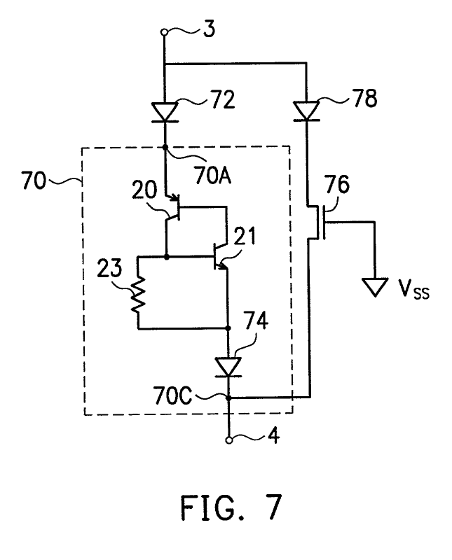

Referring to FIG. 7, a schematic circuit diagram of a fourth preferred embodiment in accordance with the present invention is illustrated. In this embodiment, an ESD protection circuit is electrically coupled between a pair of circuit nodes 3 and 4, which can be an IC pad and a V_{SS} power node, respectively. The ESD protection circuit comprises a floating-well semiconductor controlled rectifier 70 and at least one diode, where two diodes 72 and 74 are exemplified in FIG. 7.

The floating-well SCR 70 is implemented by means of the structure as shown in FIG. 1, except for the N⁺-type diffusion region 13, so that the N-well region 11 is thus floating. The floating-well SCR 70 is provided with an anode terminal 70A and a cathode terminal 70C. The diode 72 is configured with its anode and cathode connected to the circuit node 3 and the anode terminal 70A of the floating-well SCR 70, respectively. The diode 74 is configured with its anode and cathode connected to the cathode terminal 70C of the floating-well SCR 70 and the circuit node 4, respectively.

In addition, the floating-well SCR 70 is triggered by an MOS transistor 76, which is connected in series to at least one diode 78 between the circuit nodes 3 and 4. Therefore, assuming that both of the diodes 32 and 34 are provided with the same cut-in voltage V_{γ1} and N₁ represents the number of the diodes connected in series to the floating-well SCR 70, the diode 78 has a cut-in voltage V_{γ2} and N₂ represents the number of the diodes connected in series to the MOS transistor 76, the trigger voltages V_{TR1}, V_{TR2} and the holding voltages V_{H1}, V_{H2} has the following relationship:

V_{TR1}≈(V_{TR2}+N₂×V_{γ2})

V_{H1}≈(V_{H2}+N₁×V_{γ1})

Although N₁=2 and N₂=1 are exemplified in this embodiment, the required number can be one or more than two based upon the design choice so that the proper trigger voltage and holding voltage can be acquired. Generally speaking, the holding voltage V_{TR1} is adjusted to be greater than or substantially equal to V_{IH}, the ESD protection circuit of FIG. 7 can be applied at an IC input pad so as to ensure that the internal circuit 2 works properly during the circuit operation. Preferably, if the holding voltage V_{H1} can be adjusted to be greater than or substantially equal to V_{DD}, the ESD protection circuit of FIG. 3 can be thoroughly immune to latch-up phenomenon during the circuit operation, even in an environment of noise and electromagnetic interference.

In conclusion, the ESD protection circuit of the present invention comprises an SCR and at least one diode connected in series. The series-connected scheme is electrically coupled between a pair of circuit nodes. Even though the SCR enters snapback during circuit operation the diode can be utilized to increase a holding voltage between the pair of circuit nodes.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. An ESD protection circuit, comprising:
a semiconductor controlled rectifier coupled between a pair of circuit nodes; and
a diode connected in series to said semiconductor controlled rectifier;
wherein said diode increases a holding voltage between said pair of circuit nodes when said semiconductor controlled rectifier enters snapback.

2. The ESD protection circuit as claimed in claim 1, wherein said semiconductor controlled rectifier is a lateral semiconductor controlled rectifier.

3. The ESD protection circuit as claimed in claim 1, wherein said semiconductor controlled rectifier is a low voltage triggering semiconductor controlled rectifier.

4. The ESD protection circuit as claimed in claim 1, wherein said semiconductor controlled rectifier is a floating-well semiconductor controlled rectifier.

5. The ESD protection circuit as claimed in claim 4, further comprising a MOS transistor connected in parallel to said semiconductor controlled rectifier.

6. The ESD protection circuit as claimed in claim 5, further comprising another diode connected in series to said MOS transistor.

7. An ESD protection circuit, comprising:
a semiconductor controlled rectifier having a semiconductor substrate and a well formed therein, said well including an ohmic contact region; and
a diode connected in series to said semiconductor controlled rectifier between a pair of circuit nodes;
wherein said diode increases a holding voltage between pair of circuit nodes when said semiconductor controlled rectifier enters snapback.

8. The ESD protection circuit as claimed in claim 7, wherein said is a lateral semiconductor controlled rectifier.

9. The ESD protection circuit as claimed in claim 7, wherein said semiconductor controlled rectifier is a low voltage triggering semiconductor controlled rectifier.

10. An ESD protection circuit, comprising:
a semiconductor controlled rectifier having a semiconductor substrate and a floating well formed therein; and
a diode connected in series to said semiconductor controlled rectifier between a pair of circuit nodes;
wherein said diode increases a holding voltage between pair of circuit nodes when said semiconductor controlled rectifier enters snapback.

11. The ESD protection circuit as claimed in claim 10, further comprising a MOS transistor connected in parallel to said semiconductor controlled rectifier.

12. The ESD protection circuit as claimed in claim 11, further comprising another diode connected in series to said MOS transistor.
